(19) United States
(12) Patent Application Publication
(10) Pub. No.: US 2008/0237157 A1
(43) Pub. Date: Oct. 2, 2008

(54) WAFER TRANSPORT SYSTEM

(76) Inventors: Chee Keong Chin, Shanghai (CN); Wen Bin Liu, Shanghai (CN); Li Hui Lu, Shanghai (CN)

Correspondence Address: LAW OFFICES OF MIKIO ISHIMARU, 333 W. EL CAMINO REAL, SUITE 330, SUNNYVALE, CA, 94087, US

(21) Appl. No.: 11/694,929

(22) Filed: Mar. 30, 2007

(51) Int. Cl. H01L 21/00

(52) U.S. Cl. 211/41.18

(57) ABSTRACT

A wafer transport system is provided including providing a wafer cassette having a slot, and placing a protection insert into the slot.

### TECHNICAL FIELD

The present invention relates generally to wafer transport system, and more particularly to a wafer transport system for thinned wafers.

### BACKGROUND ART

Increased miniaturization of components, greater packaging density of integrated circuits (“ICs”), higher performance, and lower cost are ongoing goals of the computer industry. As new generations of IC products are released, the number of devices used to fabricate them tends to decrease due to advances in technology. Simultaneously, the functionality of these products increases.

Semiconductor package structures continue to advance toward miniaturization and thinning to increase the density of the components that are packaged therein while decreasing the sizes of the end products having the IC products. This is in response to continually increasing demands on information and communication apparatus for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook personal computers, and so forth. All of these devices continue to be made smaller and thinner to improve their portability. Accordingly, large scale IC (“LSI”) packages that are incorporated into these devices are required to be made smaller and thinner, and the package configurations that house and protect them are required to be made smaller and thinner as well.

As there are a myriad of applications and electronic products that uses integrated circuits, there are also many types of integrated circuits, integrated circuit technologies, and wafers needed. These variations may span from ingot formation through end product integration and test.

Wafers are obtained by slicing an ingot with a proper device and stowed in special cases, such as wafer cassettes or wafer boats. The wafers in the wafer cassettes are delivered to sites for after treatment, test, analysis, etc. Developing thinned integrated circuit dice may start from the wafer from which they were fabricated therefrom. Other integrated circuits may not require thinning as an after treatment but may have other after treatments or may utilize wafer of different sizes.

One common attribute in the vast number of wafer manufacturing possibilities is the need to handle, transport, and store wafers. A wafer cassette holds a plurality of wafers preventing mechanical damage and contamination during storage and transportation. However, one type of wafer cassette may be used during the manufacturing and handling wafers of different sizes and thinness. The re-use of any materials or equipments in the manufacturing process promotes cost savings in the overall manufacturing cost of integrated circuits.

For example, during wafer processing, the wafers are subjected to a number of operations performed by one or more machines. The wafers may be loaded or unloaded from the wafer cassette manually or with a robotic arm. The wafer cassette must provide sufficient space for the loading and unloading mechanism.

However, a wafer that has a large diameter and aggressively thinned will have different requirements from a wafer cassette compared to a small diameter wafer that has not been thinned. The thinned large wafers often experience warpage or bowing in the wafer cassette such that the wafer or the integrated circuit fabricated thereon may be damaged. Typically, this handling damage significantly reduces yield and increases cost of the integrated circuits.

Still thinner integrated circuits have been adopted in response to continuing requirements for further miniaturization. At the same time, increasing consumer demand for electronic products with ever-increasing miniaturization drive wafer manufacturing to larger and larger wafer sizes with thinner and thinner integrated circuits manufactured from these wafers.

Thus, a need still remains for a wafer transport system providing low cost manufacturing and improved yield for the wafer manufacturing and handling. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a wafer transport system including providing a wafer cassette having a slot, and placing a protection insert into the slot.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is an isometric view of a wafer transport system in an embodiment of the present invention;

FIG. 2 is an isometric view of the wafer transport system of FIG. 1 in an assembly phase;

FIG. 3 is an isometric view of the wafer transport system of FIG. 1 having wafers therein;

FIG. 4 is a front view of the one of the protection inserts of FIG. 3; and

FIG. 5 is a flow chart of a wafer transport system for manufacture of the wafer transport system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side”(as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

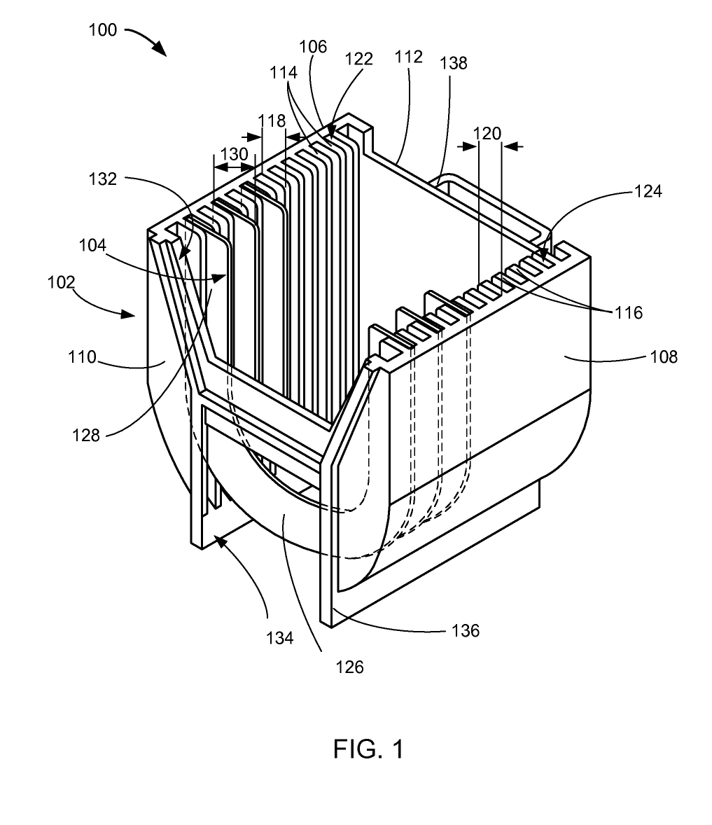

Referring now to FIG. 1, therein is shown an isometric view of a wafer transport system 100 in an embodiment of the present invention. The wafer transport system 100 includes a wafer cassette 102 and protection inserts 104 therein. The wafer cassette 102 preferably includes a first wall 106, a second wall 108, a third wall 110, and a fourth wall 112. The first wall 106 and the second wall 108 are opposing walls of the wafer transport system 100. The third wall 110 and the fourth wall 112 are opposing walls of the wafer transport system 100.

First dividers 114 and second dividers 116 are integral to the first wall 106 and the second wall 108, respectively. Each of the first dividers 114 extends into the first wall 106 by a first divider width 118. Each of the second dividers 116 extends into the second wall 108 by a second divider width 120. First slots 122 are in the first wall 106 and between the first dividers 114. Second slots 124 are in the second wall 108 and between the second dividers 116.

The protection inserts 104, such as U-wing shaped inserts, are preferably placed in the wafer cassette 102. The protection inserts 104 are preferably in the first slots 122 and the second slots 124 between the first wall 106 and the second wall 108.

Each of the protection inserts 104 includes an insert base 126 and insert columns 128. The insert base 126 is between the insert columns 128. The protection inserts 104 provide additional structural support with the insert columns 128 and the insert base 126 beyond the first dividers 114 and the second dividers 116.

The insert columns 128 are shown as linear portions of each of the protection inserts 104. Each of the insert columns 128 having an insert column width 130 extends beyond the first dividers 114 and the second dividers 116 adjacent to each of the protection inserts 104. The insert column width 130 is greater than the first divider width 118 and the second divider width 120. For example, the range for the ratio of the insert column width 130 to the first divider width 118 or the second divider width 120 is from 1.5:1 through 3:1. The protection inserts 104 may be designed or selected for a predetermined selection of the wafer cassette 102.

For illustrative purposes, the protection inserts 104 are shown in alternating locations of the first slots 122 and the second slots 124, although it is understood that the protection inserts 104 may be inserted in different locations, such as all the first slots 122 and all the second slots 124. Also for illustrative purposes, the protection inserts 104 are shown substantially the same, although it is understood that the protection inserts 104 may be different from each other, such as different sizes or configurations. The protection inserts 104 having different configurations may be placed in the wafer cassette 102.

The third wall 110 includes a first recess 132 and a second recess 134. The third wall 110 preferably has the first recess 132 with sloped sides ending at a base. The first recess 132 provides the clearance for loading and unloading the wafer cassette 102. Legs 136 of the wafer cassette 102 outline the sides of the second recess 134 in the third wall 110. The second recess 134 exposes the insert base 126 of the protection inserts 104. The legs 136 provide support of the wafer cassette 102 and clearance for the protection inserts 104.

The fourth wall 112 preferably has a handle 138 not between the first wall 106 and the second wall 108. The handle 138 is preferably used for handling the wafer cassette 102 and the wafer transport system 100.

For illustrative purposes, the wafer transport system 100 is shown including the wafer cassette 102 having the first wall 106, the second wall 108, the third wall 110, and the fourth wall 112, although it is understood that the wafer transport system 100 may include a wafer carrier (not shown) different than the wafer cassette 102, such as a wafer carrier having rods with slots for receiving the protection inserts 104. For example, a wafer carrier used in heating chambers may be used with the protection inserts 104 that are preferably configured for that particular wafer carrier.

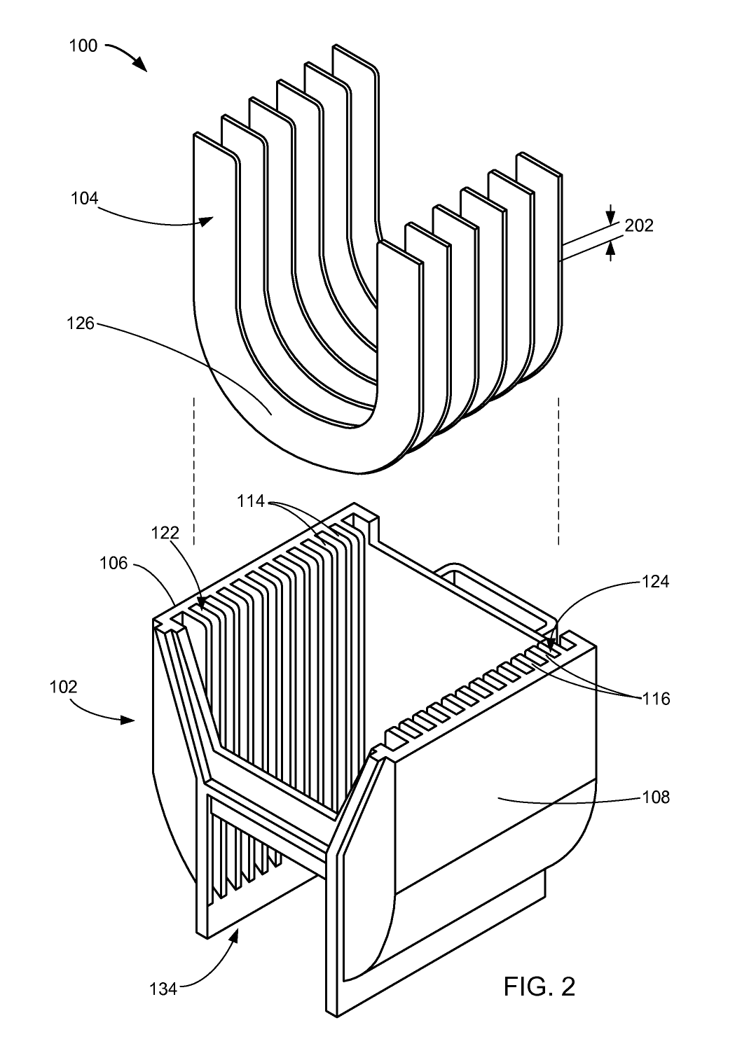

Referring now to FIG. 2, therein is shown an isometric view of the wafer transport system 100 of FIG. 1 in an assembly phase. As described earlier, the wafer transport system 100 preferably includes the wafer cassette 102. The protection inserts 104 are shown suspended above the wafer cassette 102 to be placed in the wafer cassette 102.

The protection inserts 104 are placed in the predetermined locations of the first slots 122 and the second slots 124. The insert base 126 of the protection inserts 104 are placed between the first wall 106 and the second wall 108 and exposed by the second recess 134. Each of the protection inserts 104 has an insert thickness 202 less than the first slots 122 and the second slots 124. The first slots 122 and the second slots 124 provide clearance for loading elements (not shown) into the first slots 122 and the second slots 124 having the protection inserts 104.

The protection inserts 104 may be placed in the wafer cassette 102 and may be removable. Alternatively, the protection inserts 104 may be placed in the wafer cassette 102 and may be attached to one of the first dividers 114 and one of the second dividers 116 forming the first slots 122 and the second slots 124 with one of the protection inserts 104.

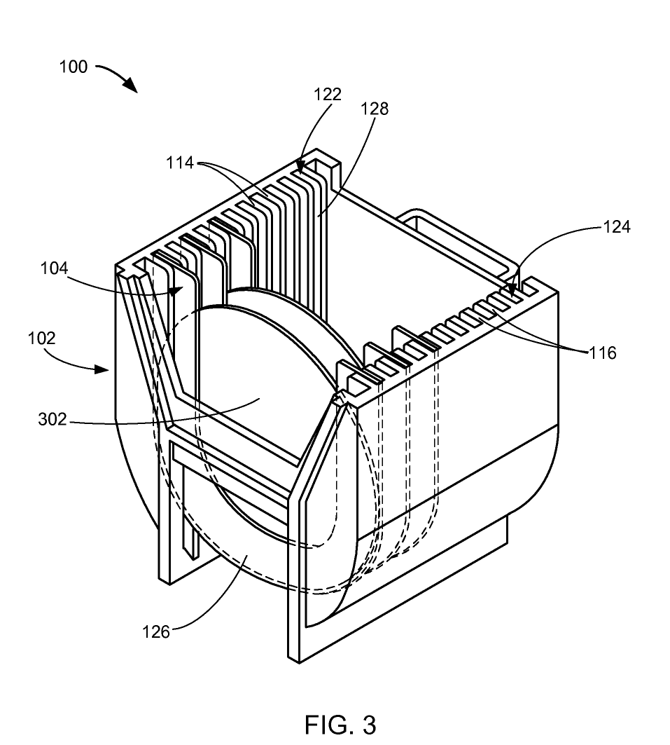

Referring now to FIG. 3, therein is shown an isometric view of the wafer transport system 100 of FIG. 1 having wafers 302 therein. The isometric view depicts the protection inserts 104 in the first slots 122 and the second slots 124 of the wafer cassette 102.

The wafers 302 are preferably placed in the first slots 122 and the second slots 124 having the protection inserts 104. The insert columns 128 provide additional surface area for each of the wafers 302 providing additional structural support more than the first dividers 114 and the second dividers 116. The insert base 126 provides surface area for each of the wafers 302 providing structural support not provided by the wafer cassette 102. The additional surface areas provided by the protection inserts 104 mitigate or eliminate warpage, bowing, or bending of the wafers 302.

For example, as the diameter of the wafers 302 increase and thinning the wafers 302 become more aggressive, the warpage, bowing, or bending of the wafers 302 may cause damage to the wafers 302 resulting in decreased yields, increased cost, and even severely hampering manufacturing output. Furthermore, the warpage, bowing, or bending of the wafers 302 may also damage some of the wafer processing equipments further reducing yields, increasing cost, and reducing manufacturing output.

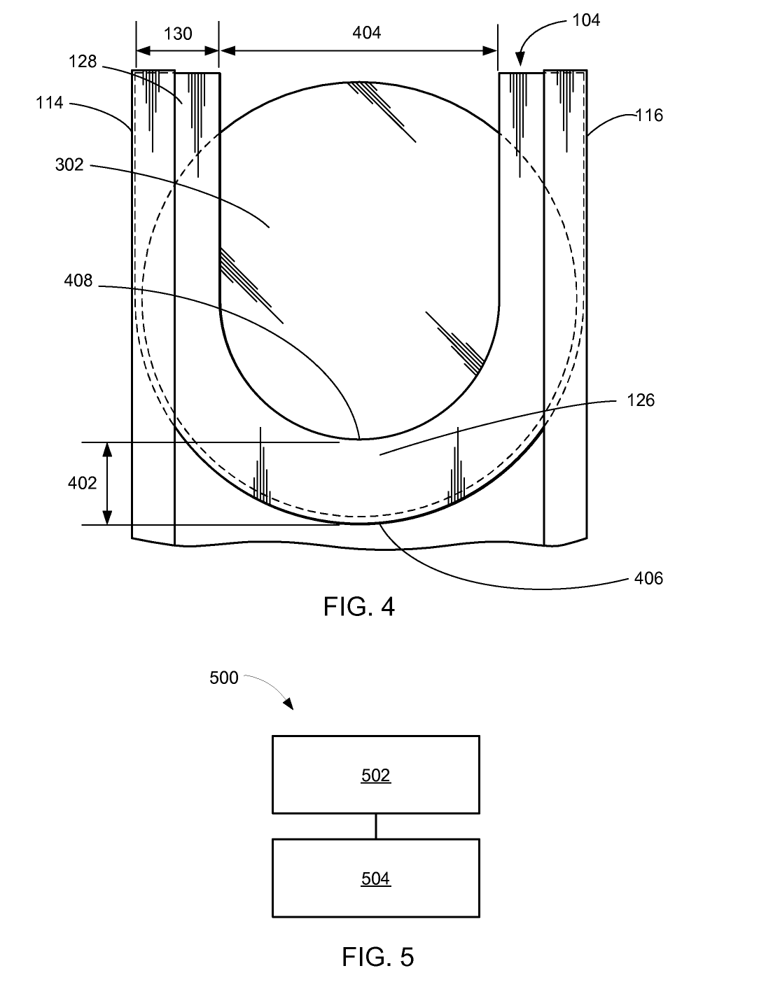

Referring now to FIG. 4, therein is shown a front view of the one of the protection inserts 104 of FIG. 3. The front view depicts one of the wafers 302 behind one of the protection inserts 104. As described earlier, each of the protection inserts 104 include the insert columns 128 with the insert column width 130 and the insert base 126. The insert base 126 has an insert base width 402.

The protection inserts 104 provide additional surface area beyond the surface are provided by the first dividers 114 and the second dividers 116 for providing structural support to the wafers 302 not provided by the wafer cassette 102 of FIG. 3 alone. The insert columns 128 support the wafers 302 behind the protection inserts 104 depicted by the dotted lines. The insert base 126 is shown as a semi-circle configuration between the insert columns 128 for also supporting the wafers 302 behind the protection inserts 104 depicted by the dotted lines.

For example, the range of ratios between the insert base width to the radius of the wafers 302 is 0.4:1 through 0.7:1. For wafers 302 having a diameter of 200 mm, the insert column width 130 is approximately in the range of 40 mm to 60 mm. For wafers 302 having a diameter of 300 mm, the insert column width 130 is approximately in the range of 75 mm to 100 mm. These ratios may vary depending on factors, such as diameter of the wafers 302 and the thickness of the wafers 302 post thinning process.

Each of the protection inserts 104 includes a gap 404 between the insert columns 128. The gap 404 provides clearance for loading and unloading the wafers 302. For illustrative purposes, the protection inserts 104 are placed in the wafer cassette 102 in FIG. 2 without the wafers 302, although it is understood that the wafers 302 and the protection inserts 104 may be placed together and jointly placed in the wafer cassette 102.

For illustrative purposes, the protection inserts 104 are shown with the insert columns 128 having the gap 404 in between and the insert base 126 also between the insert columns 128, although it is understood that the protection inserts 104 may be formed in different configurations. For example, the insert base 126 may be in a rectangular configuration between the insert columns 128 instead of the semi-circle configuration.

Another example, the insert base 126 may also a mixed geometric configuration, such as a peripheral side 406 of the insert base 126 having a semi-circle configuration and an interior side 408 of the insert base 126 having a rectangular configuration. Yet another example, the protection inserts 104 may have flexible extensions (not shown) from the insert columns 128, the insert base 126, or a combination thereof. The flexible extensions may flex in a plane of the loading and unloading force while providing additional planar rigidity in the plane or planes perpendicular to the wafers 302.

The protection inserts 104 may be formed by a number of different materials and processes. For example, the protection inserts 104 may be formed with a stamping process or a molding process. Also as an example, if the wafer cassette 102 serves to store, handle, and transport the wafers 302 without being subjected to a heating chamber, the protection inserts 104 may be formed with dielectric materials. Alternatively, if the wafer cassette 102 may be subjected to a heating chamber, the protection inserts 104 may be formed with high thermal coefficient materials to withstand the heating treatment applied to the wafer cassette 102. Some example materials for the protection inserts 104 are plastics, aluminum, or metal alloy.

Referring now to FIG. 5, therein is shown a flow chart of a wafer transport system 500 for manufacture of the wafer transport system 100 in an embodiment of the present invention. The system 500 includes providing a wafer cassette having a slot in a block 502; and placing a protection insert into the slot in a block 504.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the integrated circuit package system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit package system.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A wafer transport system comprising:
providing a wafer cassette having a slot; and
placing a protection insert into the slot.

2. The system as claimed in claim 1 further comprising placing a wafer in the slot adjacent to the protection insert.

3. The system as claimed in claim 1 wherein placing the protection insert into the slot includes:
placing a wafer adjacent to the protection insert; and
placing the wafer with the protection insert into the slot.

4. The system as claimed in claim 1 further comprising forming the protection insert having insert columns and an insert base between the insert columns.

5. The system as claimed in claim 1 wherein:
providing the wafer cassette having the slot includes:
providing the slot in a wall of the wafer cassette; and
placing the protection insert into the slot further includes:
placing the protection insert having an insert column extending from the wall.

6. A wafer transport system comprising:
providing a wafer cassette having a slot;
providing a protection insert having an insert base between insert columns and not integral with the wafer cassette; and
placing the protection insert into the slot.

7. The system as claimed in claim 6 wherein providing the protection insert having the insert base includes forming the insert base in a semi-circle configuration.

8. The system as claimed in claim 6 wherein providing the protection insert includes forming the protection insert comprised of a dielectric material.

9. The system as claimed in claim 6 wherein providing the wafer cassette having the slot include:
providing a first slot in a first wall and a second slot in a second wall, the second wall opposite the first wall; and
placing the protection insert into the first slot and the second slot.

10. The system as claimed in claim 6 further comprising placing a wafer in the slot adjacent to the insert columns and the insert base.

11. A wafer transport system comprising:
a wafer cassette having a slot; and
a protection insert in the slot.

12. The system as claimed in claim 11 further comprising a wafer in the slot adjacent to the protection insert.

13. The system as claimed in claim 11 wherein the protection insert in the slot includes a wafer adjacent to the protection insert in the slot.

14. The system as claimed in claim 11 wherein the protection insert includes insert columns and an insert base between the insert columns.

15. The system as claimed in claim 11 wherein:
the wafer cassette having the slot includes:
the slot in a wall of the wafer cassette; and
the protection insert in the slot further includes:
the protection insert having an insert column extending from the wall.

16. The system as claimed in claim 11 wherein the protection insert includes an insert base between insert columns and is not integral with the wafer cassette.

17. The system as claimed in claim 16 wherein the protection insert includes the insert base in a semi-circle configuration.

18. The system as claimed in claim 16 wherein the protection insert is comprised of a dielectric material.

19. The system as claimed in claim 16 wherein the wafer cassette having the slot include a first slot in a first wall and a second slot in a second wall, the second wall opposite the first wall, with the protection insert into the first slot and the second slot.

20. The system as claimed in claim 16 further comprising a wafer in the slot adjacent to the insert columns and the insert base.
